(19) United States
(12) Patent Application Publication
(10) Pub. No.: US 2025/0328499 A1
(43) Pub. Date: Oct. 23, 2025

(54) DATA STORAGE SYSTEM, DATA STORAGE METHOD, AND NONTRANSITORY COMPUTER READABLE MEDIUM

(71) Applicant: Mitsubishi Electric Corporation, Tokyo (JP)

(72) Inventor: Ikumi Mori, Tokyo (JP)

(73) Assignee: Mitsubishi Electric Corporation, Tokyo (JP)

(21) Appl. No.: 19/258,607

(22) Filed: Jul. 2, 2025

Related U.S. Application Data
(63) Continuation of application No. PCT/JP2023/007101, filed on Feb. 27, 2023.

(51) Int. Cl. G06F 16/174; G06F 16/182

(52) U.S. Cl. CPC G06F 16/1744; G06F 16/182

(57) ABSTRACT

A data storage system (90) that stores data that is lossy compressed includes a lossy compression device (9). The lossy compression device (9) includes a smoothness decision unit (18) that decides smoothness according to the rarity of an event indicated by subject data, as subject smoothness, and a data smoothing unit (22) that generates smoothed subject data by smoothing the subject data with the subject smoothness.

### CROSS REFERENCE TO RELATED APPLICATION

This application is a Continuation of PCT International Application No. PCT/JP2023/007101, filed on Feb. 27, 2023, which is hereby expressly incorporated by reference into the present application.

### TECHNICAL FIELD

The present disclosure relates to a data storage system, a data storage method, and a data storage program.

### BACKGROUND ART

The amount of data used in Artificial Intelligence (AI) development is generally enormous. Therefore, it is necessary to compress the data. Patent Literature 1 discloses a technique for compressing data.

### CITATION LIST

### Patent Literature

Patent Literature 1: Patent No. JP 4719667 B2

### SUMMARY OF INVENTION

### Technical Problem

A database provided by a cloud system or the like is often used as a storage location for data used in AI development. Here, it is desirable to irreversibly compress the data with the highest possible compression rate, considering the storage cost of the data. On the other hand, in AI development, in general, the utilization value of data that indicates a rare event is relatively high, while the utilization value of data that indicates a common event is relatively low. Thus, in order to compress the data at the highest possible compression rate while preserving the characteristics of the rare event, it is preferable to decide the compression rate of the data according to the rarity of the event indicated by the data. However, Patent Literature 1 does not disclose a technique for deciding the compression rate of the data according to the rarity of the event indicated by the data.

The present disclosure aims at realizing a data storage system that stores data used for AI development by lossy compression, and that decides the compression rate of the data according to the rarity of an event indicated by the data.

### Solution to Problem

A data storage system that stores data that is lossy compressed according to the present disclosure includes
a lossy compression device that includes:
a smoothness decision unit to decide smoothness according to the rarity of an event indicated by subject data, as subject smoothness; and
a data smoothing unit to generate smoothed subject data by smoothing the subject data with the subject smoothness.

### Advantageous Effects of Invention

According to the present disclosure, a smoothness decision unit decides smoothness according to the rarity of an event indicated by subject data, and a data smoothing unit smoothens the subject data with the decided smoothness. Here, the smoothness is equivalent to a compression rate. Therefore, according to the present disclosure, it is possible to realize a data storage system that stores data used for AI development by lossy compression, and that decides the compression rate of the data according to the rarity of an event indicated by the data.

### BRIEF DESCRIPTION OF DRAWINGS

FIG. 1 is a diagram describing an outline of Embodiment 1.

FIG. 2 is a diagram illustrating an example of a configuration of a data storage system 90 according to Embodiment 1.

FIG. 3 is a diagram describing functions of the data storage system 90 according to Embodiment 1.

FIG. 4 is a diagram describing probability distribution according to Embodiment 1.

FIG. 5 is a diagram describing smoothing according to Embodiment 1.

FIG. 6 is a diagram describing the smoothing according to Embodiment 1.

FIG. 7 is a diagram describing the smoothing according to Embodiment 1.

FIG. 8 is a diagram describing the smoothing according to Embodiment 1.

FIG. 9 is a diagram illustrating an example of a hardware configuration of a lossy compression device 9 according to Embodiment 1.

FIG. 10 is a flowchart illustrating processing of a data reception unit 7 according to Embodiment 1.

FIG. 11 is a flowchart illustrating processing of a data interpolation unit 10 according to Embodiment 1.

FIG. 12 is a flowchart illustrating processing of a data value calculation unit 12 according to Embodiment 1.

FIG. 13 is a flowchart illustrating processing of the data value calculation unit 12 according to Embodiment 1.

FIG. 14 is a flowchart illustrating processing of a smoothness decision unit 18 according to Embodiment 1.

FIG. 15 is a flowchart illustrating processing of a data smoothing unit 22 according to Embodiment 1.

FIG. 16 is a flowchart illustrating processing of a singular point extraction unit 24 according to Embodiment 1.

FIG. 17 is a flowchart illustrating processing of a restoration unit 28 according to Embodiment 1.

FIG. 18 is a diagram illustrating an example of the hardware configuration of the lossy compression device 9 according to a modification of Embodiment 1.

FIG. 19 is a diagram illustrating an example of the configuration of the data storage system 90 according to Embodiment 2.

FIG. 20 is a diagram describing the processing of the smoothness decision unit 18 according to Embodiment 2, wherein (a) is a diagram illustrating a specific example of a smoothness decision function 19 and (b) is a diagram illustrating a specific example of a smoothness decision table 20.

FIG. 21 is a flowchart illustrating the processing of the smoothness decision unit 18 according to Embodiment 2.

FIG. 22 is a diagram describing weights according to Embodiment 3.

FIG. 23 is a diagram illustrating an example of the configuration of the data storage system 90 according to Embodiment 4.

FIG. 24 is a diagram describing a process of distributing singular point data 25 according to Embodiment 4.

FIG. 25 is a diagram illustrating an example of the configuration of the data storage system 90 according to Embodiment 5.

FIG. 26 is a flowchart illustrating processing of a data value calculation unit 40 according to Embodiment 5.

FIG. 27 is a flowchart illustrating processing of a data storage determination unit 44 according to Embodiment 5.

### DESCRIPTION OF EMBODIMENTS

In the description and drawings of embodiments, the same elements and corresponding elements are denoted by the same reference sign. The description of elements denoted by the same reference sign will be omitted or simplified as appropriate. Arrows in the drawings mainly indicate flows of data or flows of processing. Further, “unit” may be appropriately interpreted as “circuit”, “step”, “procedure”, “process”, or “circuitry”.

### Embodiment 1

Hereafter, the present embodiment will be described in detail with reference to the drawings.

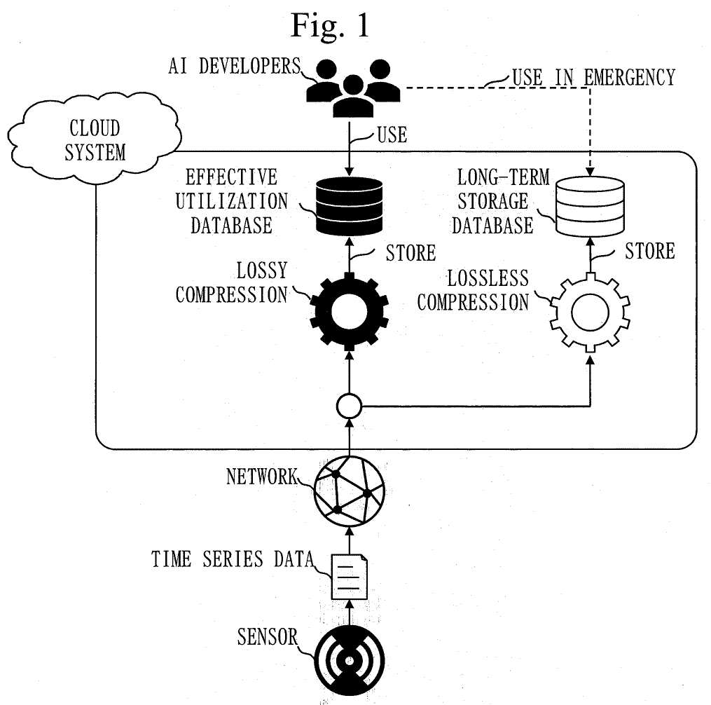

An outline of the present embodiment will be described using FIG. 1. In the storage of sensor data in the Internet of Things (IoT), there is a need for a data compression method that achieves both storage cost and effective utilization of the sensor data. The sensor data is discrete data and time series data.

Here, in a database with low storage cost, the disadvantage is that it generally takes time to extract data and it is charged each time data is input/output. Therefore, it is preferable to use the database with low storage cost as a long-term storage database.

On the other hand, in a database with high storage cost, the advantage is that data input/output is fast because it is generally possible to do a search with a standard query such as Structured Query Language (SQL). Also, in the database with high storage cost, it is charged according to the running time of the database. Therefore, it is preferable to use the database with high storage cost as an effective utilization database.

Each of the long-term storage database and the effective utilization database is, as a specific example, a database that is implemented in a cloud system.

The effective utilization database is a database that allows Artificial Intelligence (AI) developers to use data immediately, that is, a database with fast search speed. The effective utilization database stores the pre-processed data so that the AI developers can easily use the data, and also stores the lossy compressed data to reduce the amount of data. Here, it is preferable to store data compressed at the highest possible compression rate in the effective utilization database to reduce the storage cost. However, simply increasing the compression rate of the data poses the risk of losing the characteristics of the data, resulting in data that is not useful for AI development.

The long-term storage database is a database for data backup and data archival storage, and is basically operated to minimize the number of readings by accessing it only in case of emergency. Therefore, basically, there are no problems with the use of the database with low storage cost as the long-term storage database. In addition, the long-term storage database stores the data generated by lossless compression of unprocessed data.

### Description of Configuration

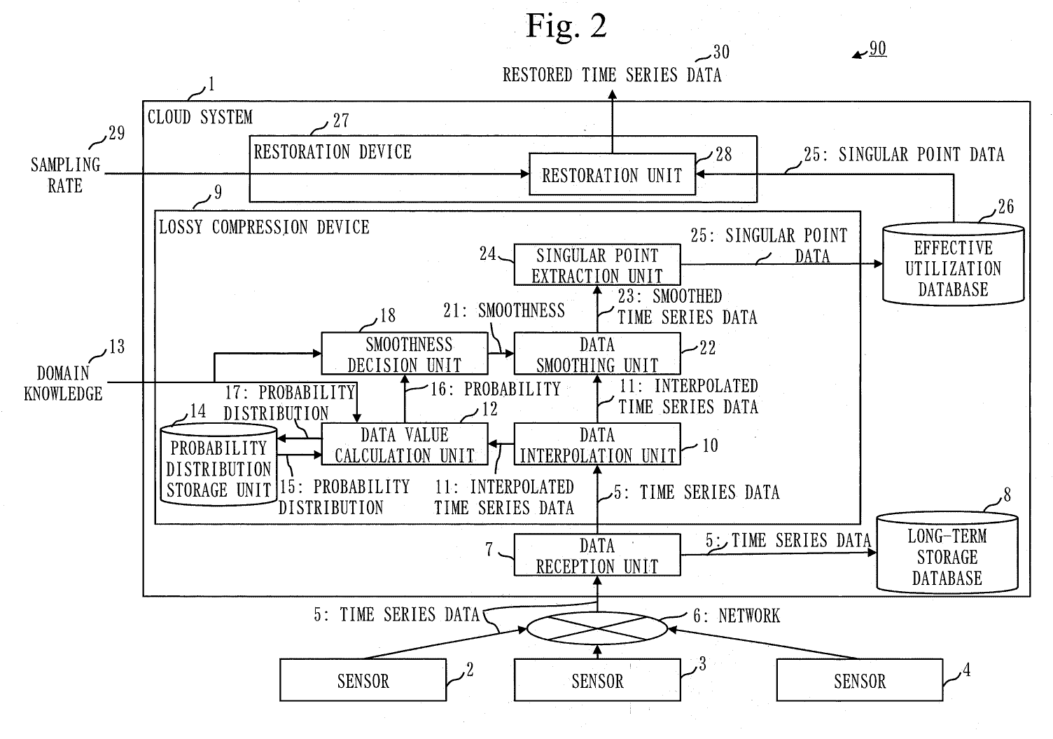

FIG. 2 illustrates an example of a configuration of a data storage system 90 according to the present embodiment. As illustrated in the present diagram, the data storage system 90 includes a cloud system 1, a sensor 2, a sensor 3, a sensor 4, and a network 6. The cloud system 1, the sensor 2, the sensor 3, and the sensor 4 are each communicatively connected via the network 6.

Each of the sensor 2, the sensor 3, and the sensor 4, periodically transits time series data 5 to the cloud system 1 via the network 6. The time series data 5 is data that indicates a measurement result of each sensor. The total number of sensors included in the data storage system 90 is not limited to 3. Each sensor may be any type of sensor.

The cloud system 1 includes a data reception unit 7, a long-term storage database 8, a lossy compression device 9, an effective utilization database 26, and a restoration device 27. The plurality of functional components of the cloud system 1 may be configured in an integrated manner as appropriate.

The long-term storage database 8 stores lossless compressed subject data. The subject data is, as a specific example, time series data that indicates a measurement result of a sensor. The time series data is, as a specific example, raw data before being processed.

The lossy compression device 9 includes a data interpolation unit 10, a data value calculation unit 12, a probability distribution storage unit 14, a smoothness decision unit 18, a data smoothing unit 22, and a singular point extraction unit 24.

The effective utilization database 26 stores lossy compressed data.

The restoration device 27 includes a restoration unit 28.

When receiving the time series data 5, the data reception unit 7 not only stores the received time series data 5 in the long-term storage database 8, but also outputs the received time series data 5 to the data interpolation unit 10.

When the sampling rate of the time series data 5 is low, the data interpolation unit 10 upsamples the time series data 5 using a moving average, Akima interpolation, spline interpolation, or the like, in order to smooth the time series data 5 into a smooth waveform. Afterward, the data interpolation unit 10 outputs the upsampled time series data 5 to each of the data value calculation unit 12 and the data smoothing unit 22, as interpolated time series data 11.

In addition, when the sampling rate of the time series data 5 is sufficiently high, the data interpolation unit 10 outputs the time series data 5 itself to each of the data value calculation unit 12 and the data smoothing unit 22, as the interpolated time series data 11.

The data value calculation unit 12 calculates either an occurrence probability of a data point indicated by the subject data or an occurrence probability of a label assigned to the subject data, as the rarity of the event indicated by the subject data. As a specific example, the data value calculation unit 12 obtains a label for identifying the event indicated by the interpolated time series data 11 from an external source, as domain knowledge 13, and also obtains a probability distribution 15 from the probability distribution storage unit 14. The event indicated by the subject data is, as a specific example, a data point or the amount of change indicated by the subject data, the label assigned to the subject data, or a state transition indicated by the subject data.

The probability distribution 15 is data that indicates the occurrence probability of an event corresponding to each label. The probability distribution 15 may be data derived from the collected time series data 5 or data provided as domain knowledge.

The data value calculation unit 12 calculates the occurrence probability of an event corresponding to a label corresponding to the interpolated time series data 11 based on the probability distribution 15, and outputs data that indicates the calculated occurrence probability to the smoothness decision unit 18, as a probability 16. When there are a plurality of labels that the interpolated time series data 11 indicates, the data value calculation unit 12 sets, for example, the label with the smallest corresponding occurrence probability among the plurality of labels, as a representative label of the interpolated time series data 11, and the occurrence probability corresponding to the representative label, as the probability 16.

Also, the data value calculation unit 12 may recalculate the probability distribution based on the probability distribution 15 and the label corresponding to the interpolated time series data 11, and may correct the probability distribution 15 by storing the recalculated probability distribution as a probability distribution 17 in the probability distribution storage unit 14.

When it is not possible to assign a label to each event, the data value calculation unit 12 may use a probability density function or the like of a data point of the interpolated time series data 11 instead of the label. In this case, the probability density function may be provided as the domain knowledge 13 or estimated from the collected time series data 5 using kernel density estimation or the like. Also in this case, by replacing the occurrence probability of an event corresponding to each label with the occurrence probability of each data point, the same processing can be implemented as the processing in the case of using labels.

The smoothness decision unit 18 decides the smoothness according to the rarity of an event indicated by the subject data, as subject smoothness. Specifically, the smoothness decision unit 18 decides smoothness 21 based on the probability 16 and the domain knowledge 13, and outputs the decided smoothness 21 to the data smoothing unit 22.

The smoothness 21 is data that indicates the degree of smoothing. The smoothness 21 is, as a specific example, the window size of a moving average, λ of smoothing spline (smoothness based on second-order derivative), or regularization term of multiple regression model (penalty term for outliers).

The smoothness decision unit 18 typically decides the smoothness 21 in units of file. The file consists of observation data for a particular day, as a specific example.

The domain knowledge 13 is, as a specific example, information that indicates things like “if the probability 16 is equal to or greater than 0.5, the smoothness is 100, and if the probability 16 is less than 0.5, the smoothness 21 is 10”. Here, 0.5 is a threshold value. Each of the smoothness and the threshold value can be regarded as domain knowledge that has been gained empirically.

The data smoothing unit 22 generates the smoothed subject data by smoothing the subject data with the subject smoothness. Specifically, the data smoothing unit 22 smoothens the interpolated time series data 11 using a value indicated by the smoothness 21 as a parameter value, and outputs the smoothed interpolated time series data 11 to the singular point extraction unit 24, as smoothed time series data 23. The data smoothing unit 22 smoothens the interpolated time series data 11 using, as a specific example, a moving average or spline smoothing. The smoothed time series data 23 is equivalent to the smoothed subject data.

The singular point extraction unit 24 extracts a plurality of singular points from the smoothed time series data 23, generates singular point data 25 that consists of the extracted plurality of singular points, and outputs the generated singular point data 25 to the effective utilization database 26.

Each singular point is, as a specific example, a starting point, an extremum (maximum point, minimum point), an inflection point, or an end point. When it is desired to reduce the number of singular points, the singular point extraction unit 24 may not consider the inflection point as a singular point.

The restoration unit 28 extracts the singular point data 25 from the effective utilization database 26 and restores data by interpolating the extracted singular point data 25 using Akima interpolation, spline interpolation, or the like with a value indicated by a sampling rate 29 given from an external source, as a parameter value. The restoration unit 28 outputs the restored data in such a manner, as restored time series data 30.

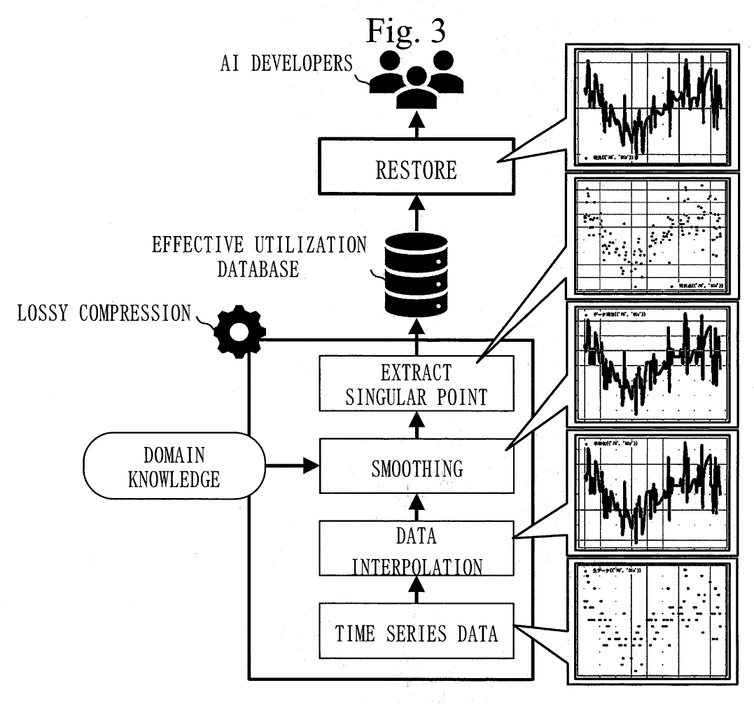

FIG. 3 is a diagram describing an outline of functions of the present embodiment.

In the present embodiment, the number of singular points is adjusted by deciding the degree of smoothing in lossy compression using the domain knowledge 13.

Here, in AI development, the utilization value of data that indicates rare events is generally high, while the utilization value of data that indicates common events is low. The rare events are those with relatively low occurrence probability. The common events are those with relatively high occurrence probability. When a combination of a plurality of events indicated by the subject data is rare, the combination of the plurality of events may be considered as a rare event, and the rarity extracted by analyzing the subject data using known methods may also be considered a rare event.

When the subject data indicates a rare event, the lossy compression device 9 lossy compresses the subject data in such a way that relatively more characteristics of the subject data remain. Specifically, the lossy compression device 9 weakens the smoothing of the subject data and performs minimal noise removal on the subject data. As for the data processing method, since the preferred processing method differs according to the goals of AI development or the like, AI developers may choose processing methods as appropriate.

Additionally, when the subject data indicates a common event, the lossy compression device 9 lossy compresses the subject data in such a way that only the trend of the subject data remains. Specifically, the lossy compression device 9 reduces the amount of data by strengthening the smoothing of the subject data. Data processing may also be performed in the effective utilization database 26.

The domain knowledge 13 indicates, as a specific example, the occurrence probability of a label or an event. The label indicates, as a specific example, a positive example, a negative example, an event, or an identifier. The average information content (entropy) indicated in [Formula 1] may be used instead of the occurrence probability of an event. When the entropy is used, an event with a high entropy is considered to be equivalent to an event with a low occurrence probability, and an event with a low entropy is considered to be equivalent to an event with a high occurrence probability.

$$H ( P ) = - {\sum }_{x ∈ U} Pr ( X = x ) log Pr ( X = x ) \qquad [ Formula 1 ]$$

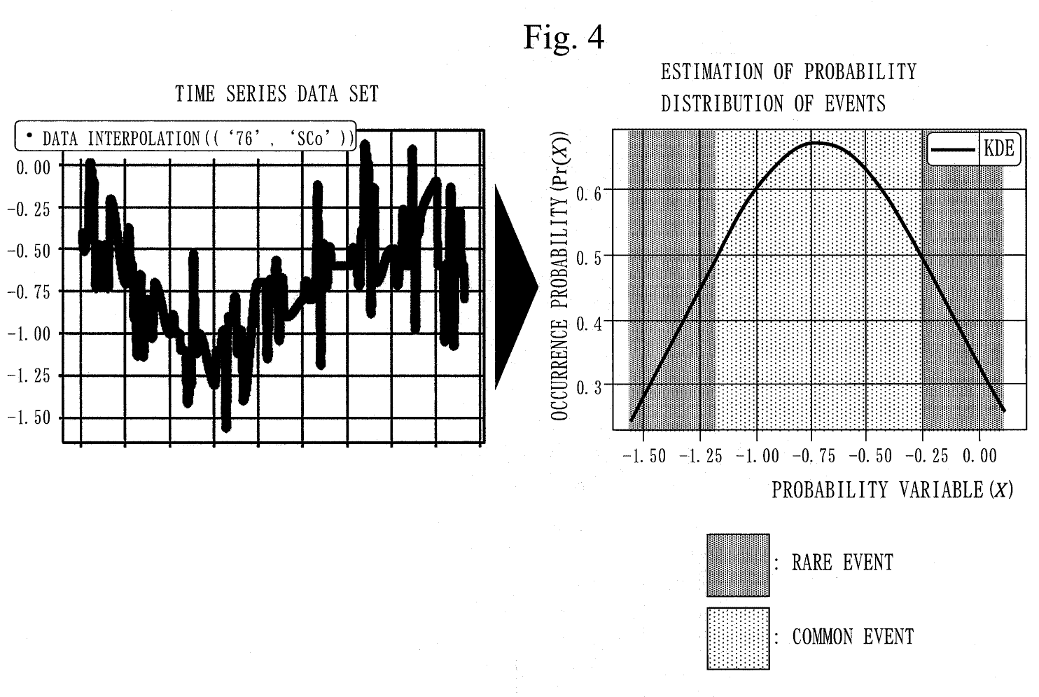

FIG. 4 is a diagram that describes a case of using the occurrence probability of events as the domain knowledge 13. The occurrence probability of each event is, as a specific example, a probability estimated based on a time series data set that consists of collected time series data, as illustrated in FIG. 4. Here, the time series data is interpolated data, and the probability variable indicates each event. Each of the time series data written in the present description may be referred to collectively as simply “time series data”. KDE is abbreviation for Kernel Density Estimation.

Further, in FIG. 4, when the occurrence probability of each event is equal to or less than a predetermined threshold value, each event is classified as a rare event, and when the occurrence probability of each event is greater than the predetermined threshold value, each event is classified as a common event.

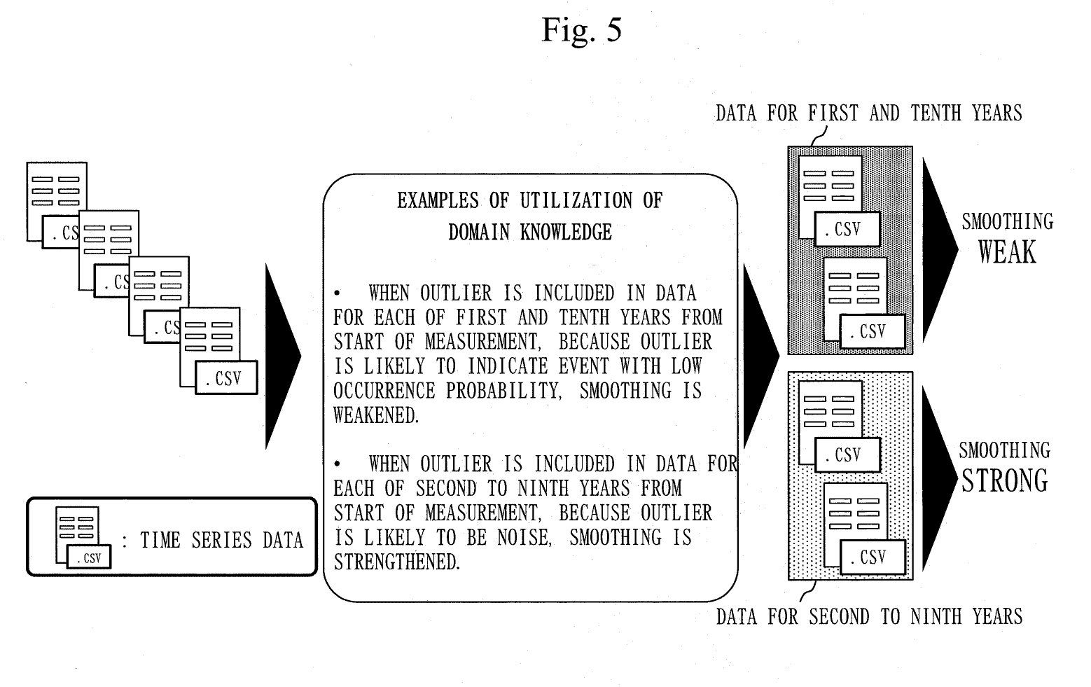

The domain knowledge and the smoothing will be described specifically with reference to FIG. 5. In FIG. 5, ten years of measurement data is collected and the measurement data is divided according to the number of years elapsed since the start of the measurement.

Here, it is assumed that the domain knowledge 13 is given that indicates that “when an outlier is included in the data for each of the first and tenth years from the start of the measurement, the data is likely to indicate an event with a low occurrence probability”. At this time, when these pieces of data actually include outliers, the lossy compression device 9 weakens the smoothing of these pieces of data.

Further, it is assumed that the domain knowledge 13 is given that indicates that “when an outlier is included in the data for each of the second to ninth years from the start of the measurement, the outlier is likely to be noise”. At this time, when these pieces of data actually include outliers, the lossy compression device 9 strengthens the smoothing of these pieces of data.

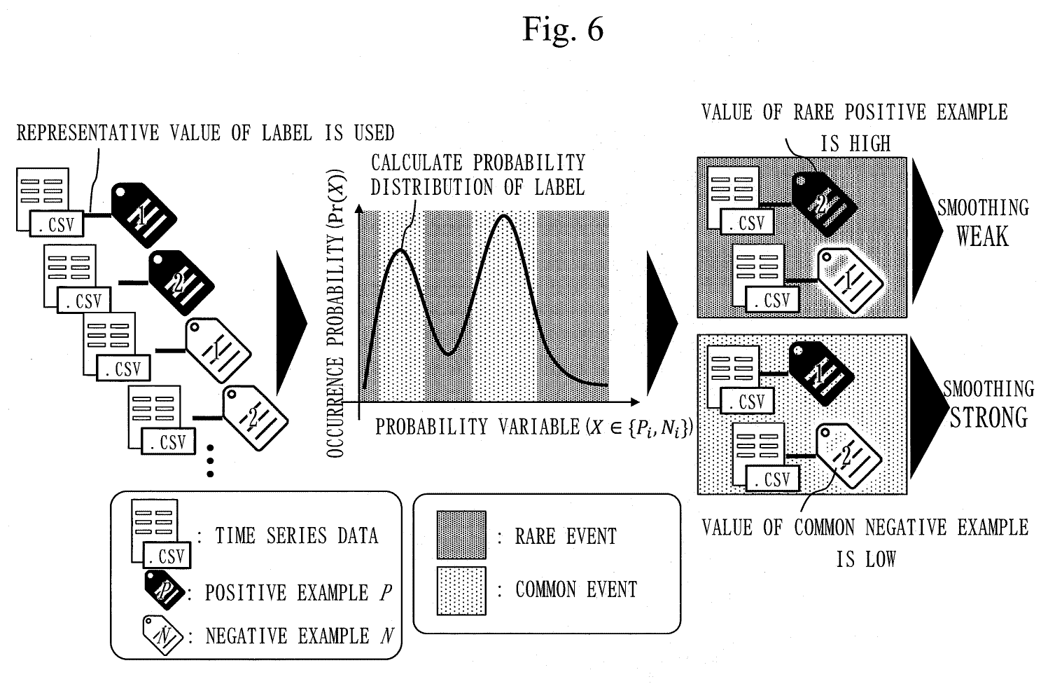

FIG. 6 illustrates how the usefulness of each time series data is determined from a single label assigned to each time series data, and the degree of smoothing of each time series data is automatically decided. In FIG. 6, a representative value of the label corresponding to each time series data is used as the label of each time series data, and each label indicates a positive or negative example.

In the example illustrated in FIG. 6, when each time series data to which the label is assigned is given, the lossy compression device 9 calculates the probability distribution of the event corresponding to each label, determines the usefulness of each time series data to which the label is assigned, using the calculated probability distribution, and automatically decides the degree of smoothing of each time series data based on a determination result. The probability distribution may be provided in advance as the domain knowledge 13.

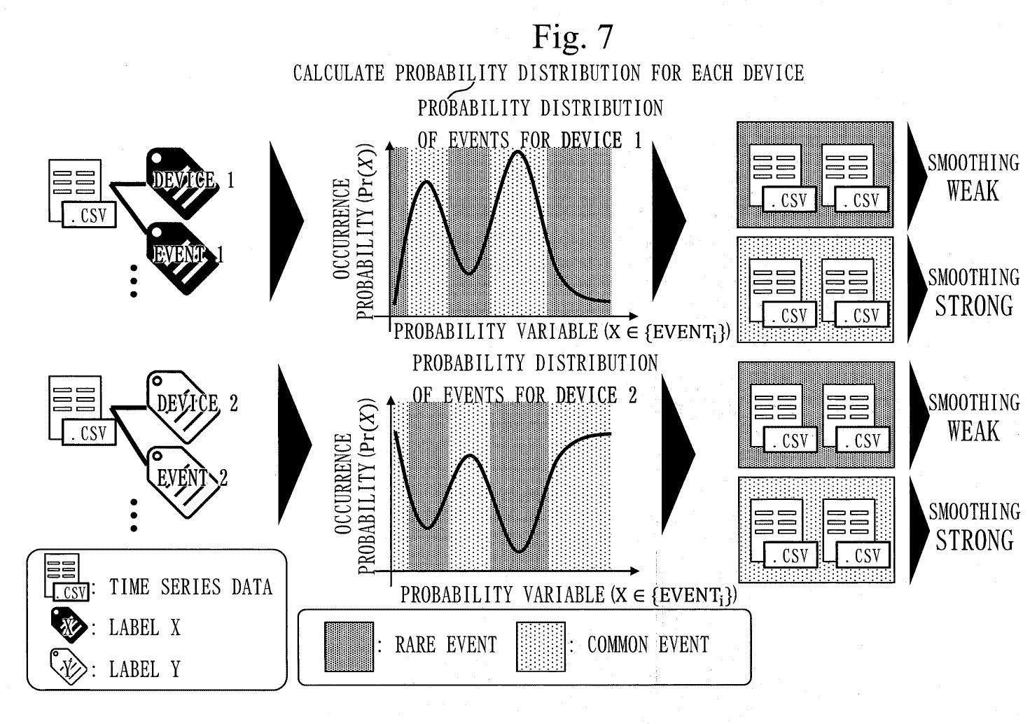

FIG. 7 illustrates how the usefulness of the time series data is determined from a plurality of labels and the degree of smoothing is automatically decided. In FIG. 7, the time series data is prepared for each device, and each time series data is data that indicates an event corresponding to each time series data. The occurrence probability of each event may be different for each device.

In the example shown in FIG. 7, the lossy compression device 9 calculates the probability distribution of each event for each device and automatically determines the degree of smoothing of each time series data using the calculated probability distribution.

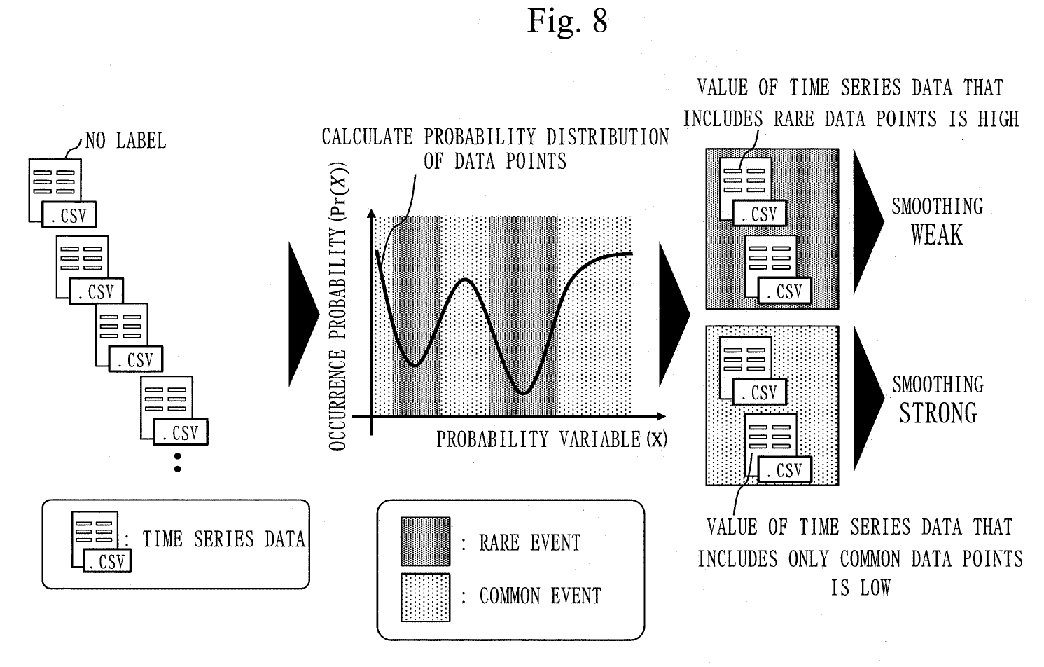

FIG. 8 illustrates how the usefulness of the time series data is determined from the frequency distribution of the data points, and the degree of smoothing is automatically decided. In FIG. 8, no label is assigned to each time series data.

In the example illustrated in FIG. 8, the lossy compression device 9 calculates probability distribution of the data points based on the collected time series data, and automatically decides the degree of smoothing for each time series data, using the calculated probability distribution. The probability distribution indicates the occurrence probability of each data point. The probability distribution may be provided in advance as the domain knowledge 13.

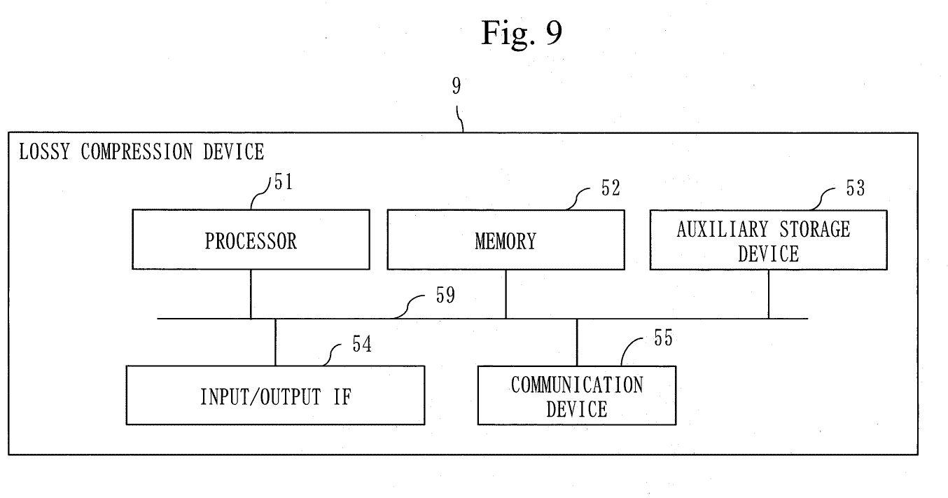

FIG. 9 illustrates an example of a hardware configuration of the lossy compression device 9 according to the present embodiment. The lossy compression device 9 consists of a computer. The lossy compression device 9 may consist of plurality of computers. A hardware configuration of other functional components that configure the data storage system 90 may be the same as the hardware configuration of the lossy compression device 9.

The lossy compression device 9 is a computer that includes pieces of hardware such as a processor 51, a memory 52, an auxiliary storage device 53, an input/output Interface (IF) 54, a communication device 55, and the like, as illustrated in the present diagram. These pieces of hardware are connected via signal lines 59 as appropriate.

The processor 51 is an Integrated Circuit (IC) that performs arithmetic operation and controls the hardware included in the computer. The processor 51 is, as a specific example, a Central Processing Unit (CPU), a Digital Signal Processor (DSP), or a Graphics Processing Unit (GPU).

The lossy compression device 9 may include a plurality of processors in place of the processor 51. The plurality of processors share the role of the processor 51.

The memory 52 is typically a volatile storage device. The memory 52 is, as a specific example, a Random Access Memory (RAM). The memory 52 is also referred to as a main storage device or a main memory. Data stored in the memory 52 is saved in the auxiliary storage device 53 as necessary.

The auxiliary storage device 53 is typically a non-volatile storage device. The auxiliary storage device 53 is, as a specific example, a Read Only Memory (ROM), a Hard Disk Drive (HDD), or a flash memory. Data stored in the auxiliary storage device 53 is loaded into the memory 52 as necessary.

The memory 52 and the auxiliary storage device 53 may be configured integrally.

The input/output IF 54 is a port to which an input device and an output device are connected. The input/output IF 54 is, as a specific example, a Universal Serial Bus (USB) terminal. The input device is, as specific examples, a keyboard and a mouse. The output device is, as a specific example, a display.

The communication device 55 is a receiver and a transmitter. The communication device 55 is, as a specific example, a communication chip or a Network Interface Card (NIC).

When communicating with another device or the like, each unit of the lossy compression device 9 may appropriately use the input/output IF 54 and the communication device 55.

The auxiliary storage device 53 stores a data storage program. The data storage program is a program that causes the computer to implement a function of each unit of the lossy compression device 9. The data storage program is loaded into the memory 52 and executed by the processor 51. The function of each unit included in the lossy compression device 9 is implemented by software.

Data used when the data storage program is executed, data obtained by executing the data storage program, and the like are appropriately stored in the storage device. Each unit of the lossy compression device 9 appropriately uses the storage device. The storage device includes at least one of the memory 52, the auxiliary storage device 53, a register in the processor 51, and a cache memory in the processor 51, as a specific example. Note that the term data and the term information may have the same meaning. The storage device may be independent of the computer.

Functions of the memory 52 and the auxiliary storage device 53 may be implemented by another storage device.

The data storage program may be recorded in a computer readable non-volatile recording medium. The non-volatile storage medium is, as a specific example, an optical disc or a flash memory. The data storage program may be provided as a program product.

### Description of Operation

An operation procedure of the data storage system 90 is equivalent to a data storage method. Also, a program that implements operation of the data storage system 90 is equivalent to the data storage program.

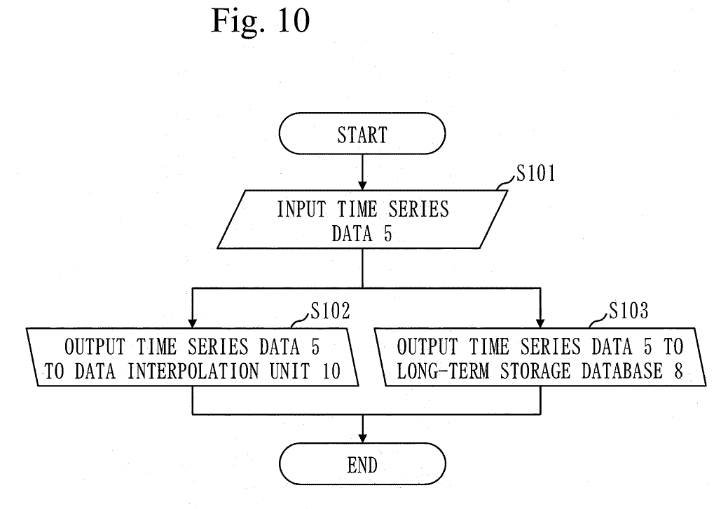

FIG. 10 is a flowchart illustrating an example of processing of the data reception unit 7. The processing of the data reception unit 7 will be described with reference to FIG. 10.

### (Step S101)

The data reception unit 7 receives the time series data 5 from each sensor via the network 6.

### (Step S102)

The data reception unit 7 outputs the received time series data 5 to the data interpolation unit 10.

### (Step S103)

The data reception unit 7 outputs the received time series data 5 to the long-term storage database 8.

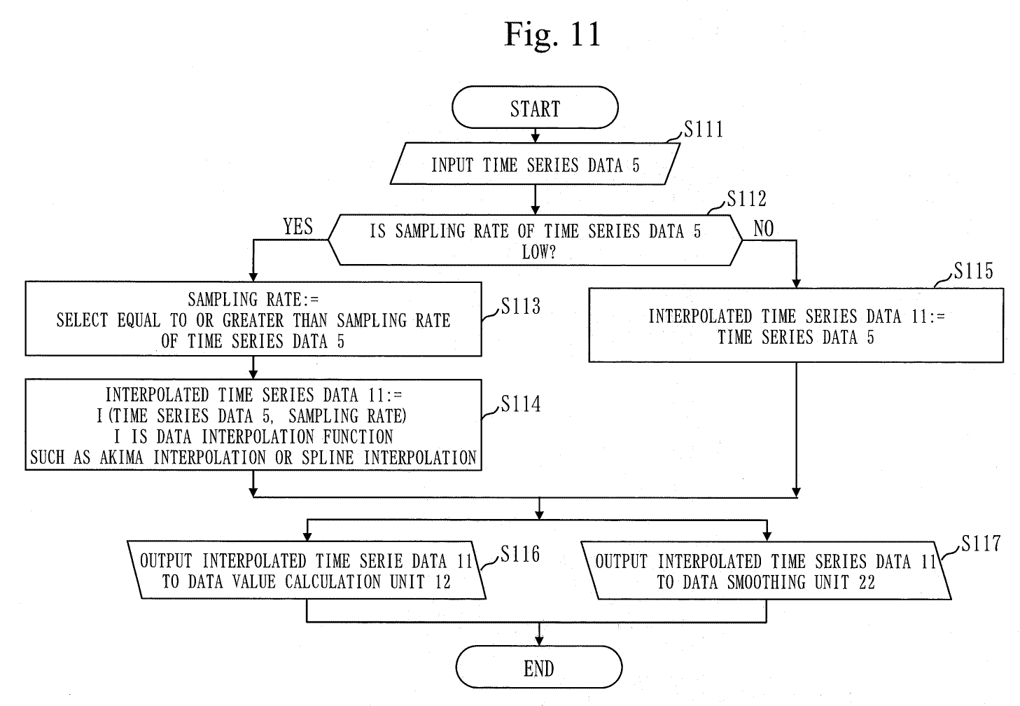

FIG. 11 is a flowchart illustrating an example of processing of the data interpolation unit 10. The processing of the data interpolation unit 10 will be described with reference to FIG. 11.

### (Step S111)

The data interpolation unit 10 receives the time series data 5 from the data reception unit 7. In addition, the data interpolation unit 10 may receive a plurality of pieces of time series data 5. When the data interpolation unit 10 receives the plurality of pieces of time series data 5, the data interpolation unit 10 executes the following processes for each received time series data 5.

### (Step S112)

When the sampling rate of the received time series data 5 is lower than the predetermined threshold value, the data interpolation unit 10 proceeds to step S113. Otherwise, the data interpolation unit 10 proceeds to step S115.

### (Step S113)

The data interpolation unit 10 selects the sampling rate that is equal to or greater than the sampling rate of the received time series data 5.

### (Step S114)

The data interpolation unit 10 generates the interpolated time series data 11 by upsampling the received time series data 5 using the selected sampling rate and a data interpolation function.

### (Step S115)

The data interpolation unit 10 treats the received time series data 5 as the interpolated time series data 11.

### (Step S116)

The data interpolation unit 10 outputs the interpolated time series data 11 to the data value calculation unit 12.

### (Step S117)

The data interpolation unit 10 outputs the interpolated time series data 11 to the data smoothing unit 22.

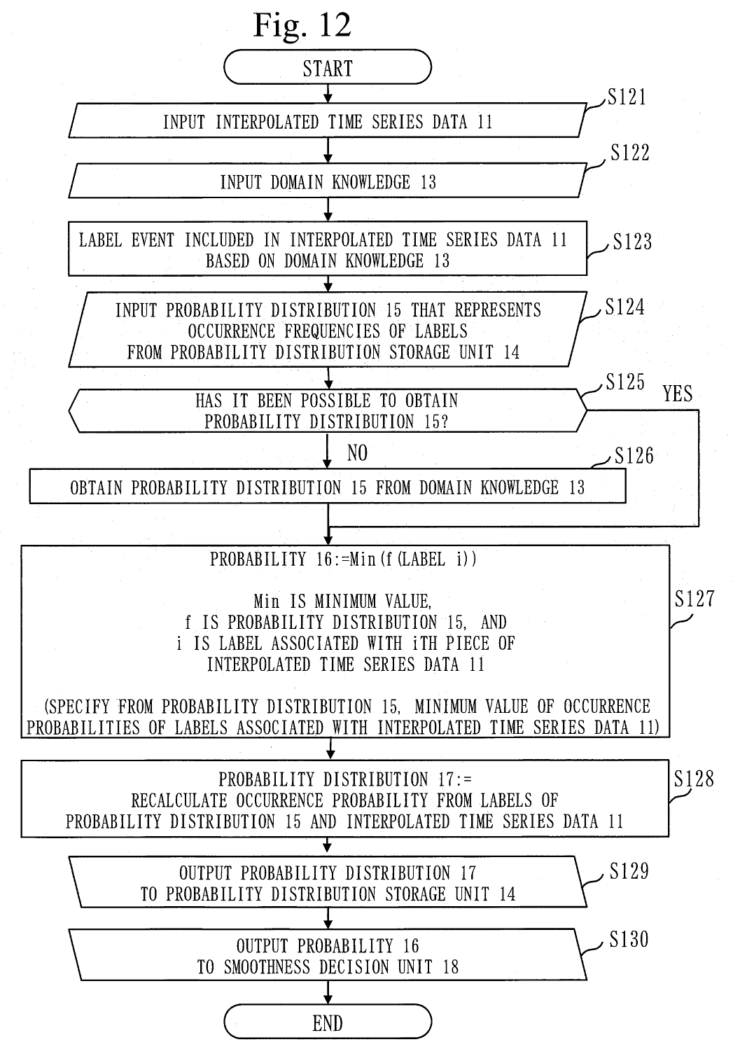

FIG. 12 is a flowchart illustrating an example of processing of the data value calculation unit 12 when a label is used. The processing of the data value calculation unit 12 will be described with reference to FIG. 12.

### (Step S121)

The data value calculation unit 12 receives the interpolated time series data 11 from the data interpolation unit 10. The data value calculation unit 12 may receive a plurality of pieces of interpolated time series data 11. When the data value calculation unit 12 receives the plurality of pieces of interpolated time series data 11, the data value calculation unit 12 executes the following processes for each piece of the received interpolated time series data 11.

### (Step S122)

The data value calculation unit 12 receives the domain knowledge 13 from an external source.

### (Step S123)

The data value calculation unit 12 labels an event indicated by the interpolated time series data 11 based on the received domain knowledge 13.

### (Step S124)

The data value calculation unit 12 receives from the probability distribution storage unit 14, the probability distribution 15 that represents the occurrence probability of each label.

### (Step S125)

When the data value calculation unit 12 has been able to obtain the probability distribution 15, the data value calculation unit 12 proceeds to step S127. Otherwise, the data value calculation unit 12 proceeds to step S126.

### (Step S126)

The data value calculation unit 12 obtains the probability distribution 15 from the domain knowledge 13.

### (Step S127)

The data value calculation unit 12 specifies the minimum value of the occurrence probability corresponding to each label associated with the interpolated time series data 11 based on the probability distribution 15, as the probability 16.

### (Step S128)

The data value calculation unit 12 recalculates the occurrence probability of each label based on each label corresponding to the probability distribution 15 and the interpolated time series data 11, and generates the probability distribution 17 based on the probability distribution 15 and the recalculated occurrence probability.

### (Step S129)

The data value calculation unit 12 outputs the generated probability distribution 17 to the probability distribution storage unit 14.

### (Step S130)

The data value calculation unit 12 outputs the probability 16 to the smoothness decision unit 18.

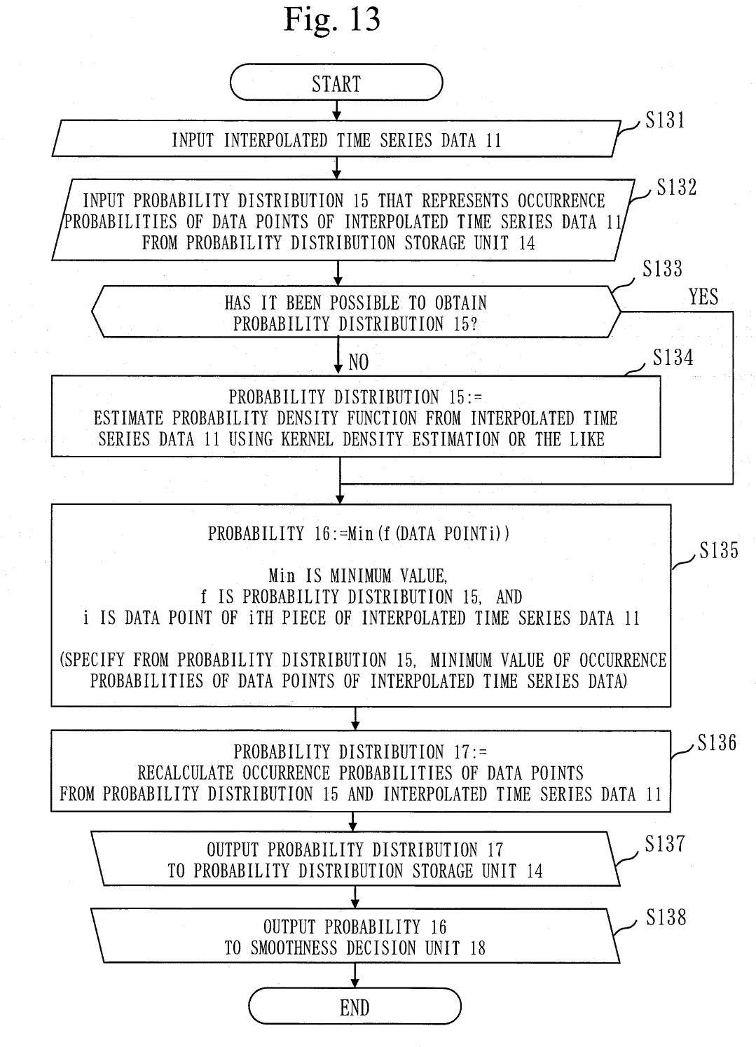

FIG. 13 is a flowchart illustrating an example of processing of the data value calculation unit 12 when the occurrence probabilities of the data points are used. The processing of the data value calculation unit 12 will be described with reference to FIG. 13.

### (Step S131)

The present step is the same as step S121.

### (Step S132)

The data value calculation unit 12 receives from the probability distribution storage unit 14, the probability distribution 15 that represents the occurrence probability of each data point indicated by the interpolated time series data 11.

### (Step S133)

When the data value calculation unit 12 is able to obtain the probability distribution 15, the data value calculation unit 12 proceeds to step S135. Otherwise, the data value calculation unit 12 proceeds to step S134.

### (Step S134)

The data value calculation unit 12 estimates the probability density function using kernel density estimation or the like based on the received interpolated time series data 11, and the estimated probability density function is treated as the probability distribution 15.

### (Step S135)

The data value calculation unit 12 specifies the minimum value of the occurrence probability of each data point indicated by the interpolated time series data 11 based on the probability distribution 15, as the probability 16.

### (Step S136)

The data value calculation unit 12 recalculates the occurrence probability of each data point based on the probability distribution 15 and the interpolated time series data 11, and generates the probability distribution 17 based on the probability distribution 15 and the recalculated occurrence probability.

### (Step S137)

The present step is the same as step S129.

### (Step S138)

The present step is the same as step S130.

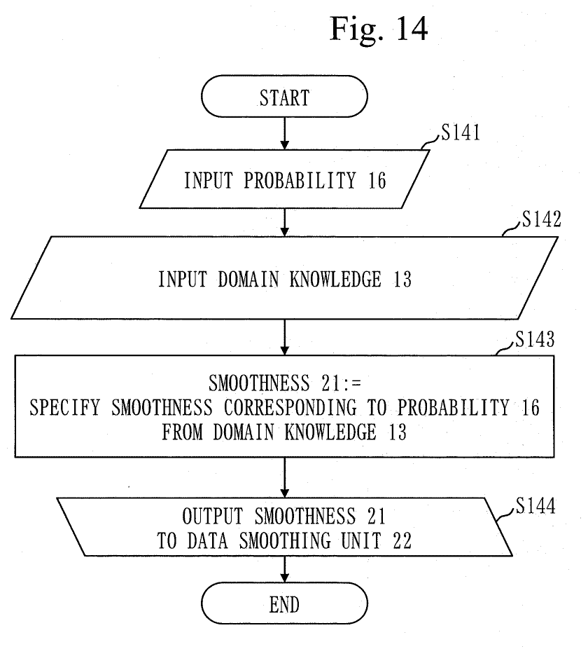

FIG. 14 is a flowchart illustrating an example of processing of the smoothness decision unit 18. The processing of the smoothness decision unit 18 will be described with reference to FIG. 14.

### (Step S141)

The smoothness decision unit 18 receives the probability 16 from the data value calculation unit 12.

### (Step S142)

The smoothness decision unit 18 receives the domain knowledge 13 from an external source.

### (Step S143)

The smoothness decision unit 18 specifies the smoothness 21 corresponding to the probability 16 based on the received domain knowledge 13.

### (Step S144)

The smoothness decision unit 18 outputs the specified smoothness 21 to the data smoothing unit 22.

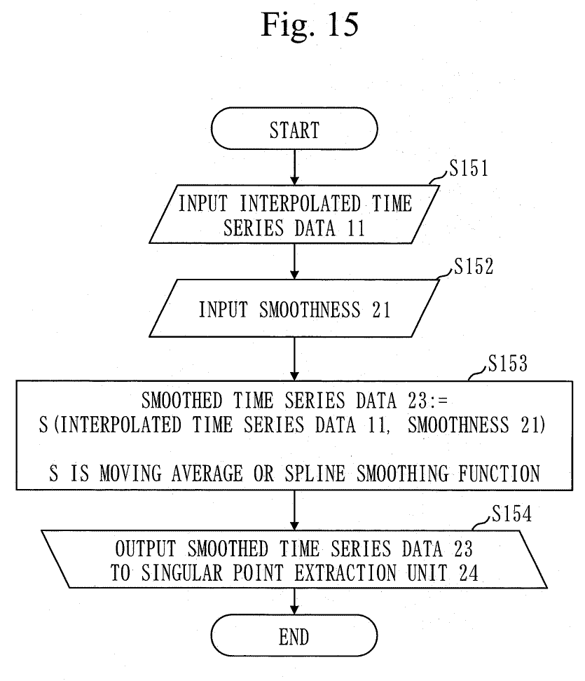

FIG. 15 is a flowchart illustrating an example of processing of the data smoothing unit 22. The processing of the data smoothing unit 22 will be described with reference to FIG. 15.

### (Step S151)

The data smoothing unit 22 receives the interpolated time series data 11 from the data interpolation unit 10.

### (Step S152)

The data smoothing unit 22 receives the smoothness 21 from the smoothness decision unit 18.

### (Step S153)

The data smoothing unit 22 generates the smoothed time series data 23 that is data smoothed from the received interpolated time series data 11, using the received interpolated time series data 11 and the received smoothness 21, and a moving average, a spline smoothing function, or the like.

### (Step S154)

The data smoothing unit 22 outputs the generated smoothed time series data 23 to the singular point extraction unit 24.

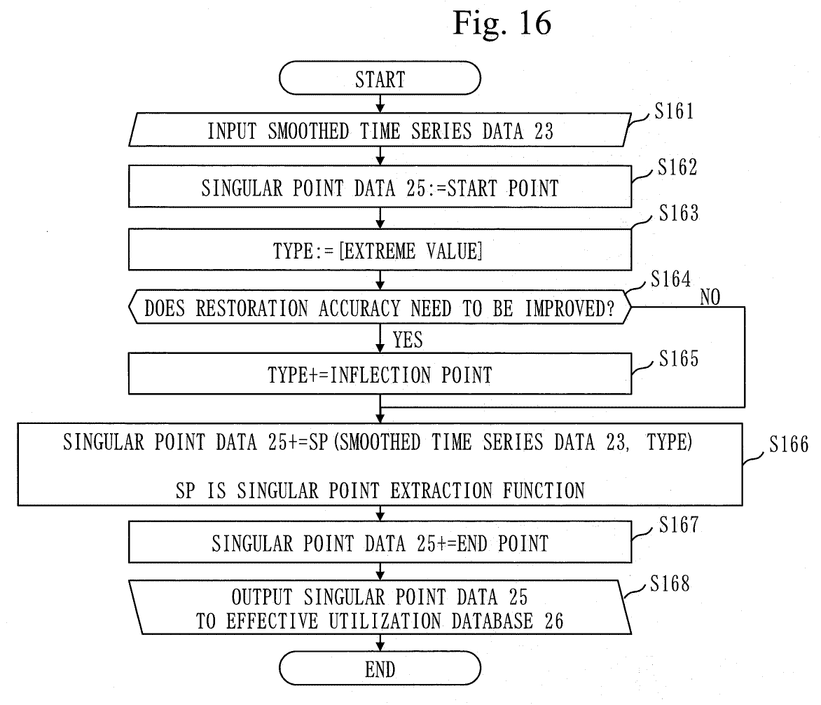

FIG. 16 is a flowchart illustrating an example of processing of the singular point extraction unit 24. The processing of the singular point extraction unit 24 will be described with reference to FIG. 16.

### (Step S161)

The singular point extraction unit 24 receives the smoothed time series data 23 from the data smoothing unit 22.

### (Step S162)

The singular point extraction unit 24 includes the start point of the smoothed time series data 23 in the singular point data 25.

### (Step S163)

The singular point extraction unit 24 includes “extreme value” in “type”. “Type” is a type of a singular point to be included in the singular point data 25. “Extreme value” indicates that the maximal point and the minimal point are included in the singular point data 25.

### (Step S164)

When the restoration accuracy needs to be improved, the singular point extraction unit 24 proceeds to step S165. Otherwise, the singular point extraction unit 24 proceeds to step S166.

### (Step S165)

The singular point extraction unit 24 adds “inflection point” to “type”.

### (Step S166)

The singular point extraction unit 24 extracts from the smoothed time series data 23, each data point that corresponds to “type”, using a singular point extraction function, and adds the extracted each data point to the singular point data 25.

### (Step S167)

The singular point extraction unit 24 adds the end point of the smoothed time series data 23 to the singular point data 25.

### (Step S168)

The singular point extraction unit 24 outputs the generated singular point data 25 to the effective utilization database 26.

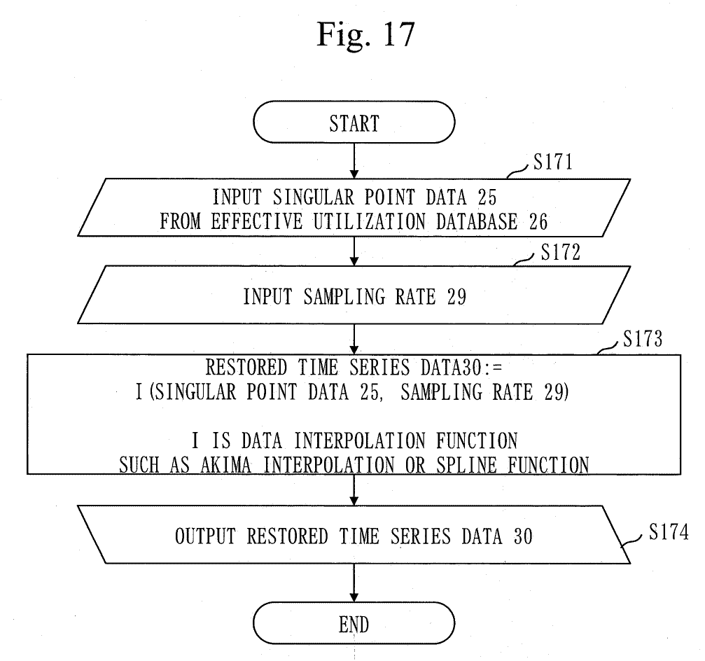

FIG. 17 is a flowchart illustrating an example of processing of the restoration unit 28. The processing of the restoration unit 28 will be described with reference to FIG. 17.

### (Step S171)

The restoration unit 28 receives the singular point data 25 from the effective utilization database 26.

### (Step S172)

The restoration unit 28 receives the sampling rate 29 from an external source.

### (Step S173)

The restoration unit 28 generates the restored time series data 30 using the singular point data 25, the sampling rate 29 and a data interpolation function such as Akima interpolation or spline interpolation.

### (Step S174)

The restoration unit 28 outputs the generated restored time series data 30.

### Description of Effects of Embodiment 1

In general, common events are overwhelmingly more numerous than rare events. Therefore, according to the present embodiment, by compressing the data corresponding to common events at a high compression rate and the data corresponding to rare events at a low compression rate, it is possible to significantly reduce the amount of data while preserving the characteristics of rare events.

In addition, according to the present embodiment, when restoring data, the restoration unit 28 is able to interpolate data at arbitrary granularity based on each singular point. Therefore, according to the present embodiment, it is possible to restore data to match the required sampling rate in AI learning. When the restoration unit 28 restores data to match a high sampling rate, an improvement in model accuracy is expected.

Moreover, in the present embodiment, when singular points are limited to only extreme values, the amount of data can be further reduced. Here, including both extreme values and inflection points in the singular points improves the accuracy of data restoration. Therefore, according to the present embodiment, depending on the effective utilization use case of the data, it is possible to appropriately select the data size and accuracy of restoration.

### Other Configurations

### <Modification 1>

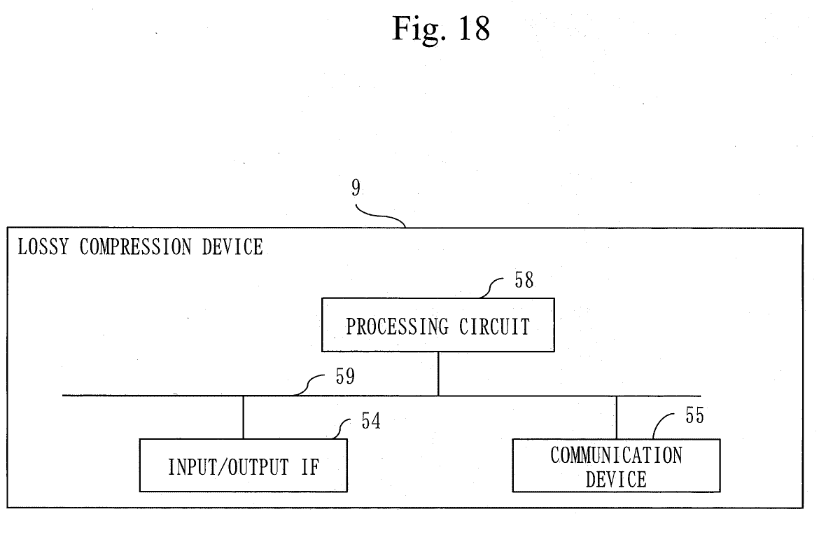

FIG. 18 illustrates an example of the hardware configuration of the lossy compression device 9 according to the present modification.

The lossy compression device 9 includes a processing circuit 58 in place of the processor 51, the processor 51 and the memory 52, the processor 51 and the auxiliary storage device 53, or the processor 51, the memory 52, and the auxiliary storage device 53.

The processing circuit 58 is hardware that implements at least part of each unit included in the lossy compression device 9.

The processing circuit 58 may be dedicated hardware, or a processor that executes a program stored in the memory 52.

When the processing circuit 58 is dedicated hardware, the processing circuit 58 is, as a specific example, a single circuit, a composite circuit, a programmed processor, a parallel programmed processor, an Application Specific Integrated Circuit (ASIC), a Field Programmable Gate Array (FPGA), or a combination thereof.

The lossy compression device 9 may include a plurality of processing circuits in place of the processing circuit 58. The plurality of processing circuits may share the role of the processing circuit 58.

In the lossy compression device 9, some functions may be implemented by dedicated hardware, while the remaining functions may be implemented by software or firmware.

The processing circuit 58 is implemented by hardware, software, firmware, or a combination thereof, as a specific example.

The processor 51, the memory 52, the auxiliary storage device 53, and the processing circuit 58 are collectively referred to as “processing circuitry”. That is, the functions of the individual functional components of the lossy compression device 9 are implemented by the processing circuitry.

The hardware configuration of other functional components that configure the data storage system 90 may be the same configuration of the present modification. The lossy compression device 9 according to the other embodiments may have the same configuration as in the present modification.

### Embodiment 2

In the following, the points that are different from the embodiment described above will be mainly described with reference to the drawings.

### Description of Configuration

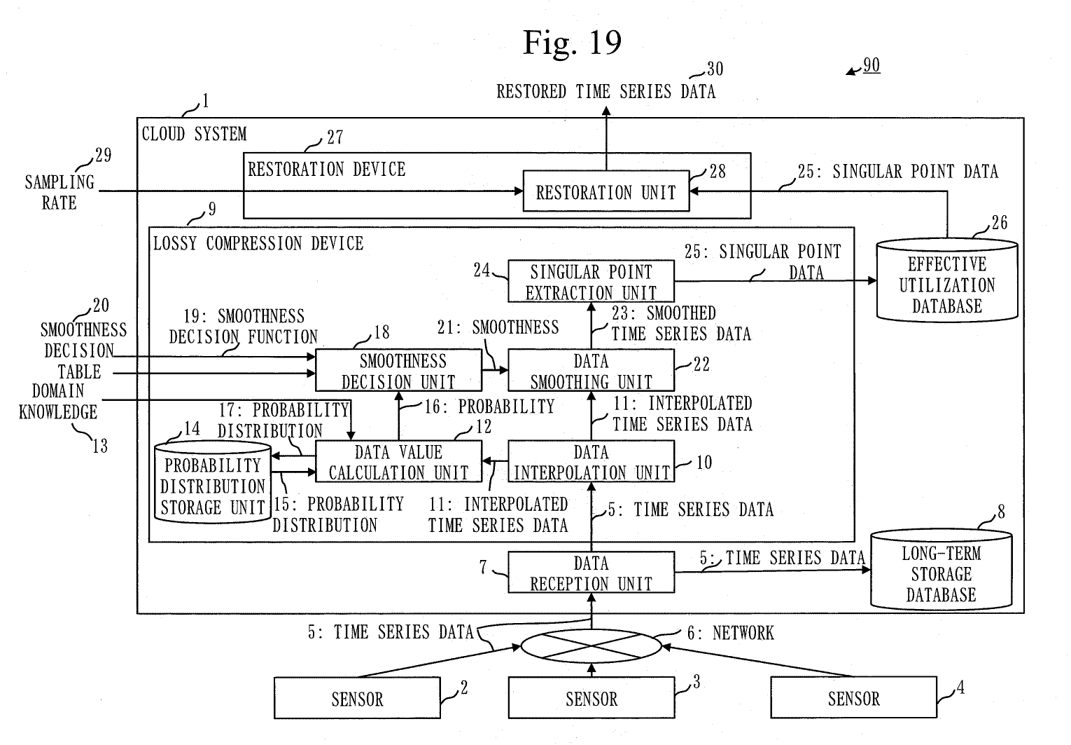

FIG. 19 illustrates an example of the configuration of the data storage system 90 according to the present embodiment.

The smoothness decision unit 18 according to the present embodiment decides the subject smoothness using data that indicates a relation between the rarity of an event indicated by the subject data and the smoothness. Specifically, the smoothness decision unit 18 decides the smoothness 21 without receiving the domain knowledge 13, but using the probability 16 and either a smoothness decision function 19 or a smoothness decision table 20. Each of the smoothness decision function 19 and the smoothness decision table 20 is equivalent to the data that indicates the relation between the rarity of the event indicated by the subject data and the smoothness. The domain knowledge 13 may also indicate the data that indicates the relation between the rarity of the event indicated by the subject data and the smoothness.

The smoothness decision function 19 is a function that indicates a relation between the rarity of an event and the smoothness. The smoothness decision function 19 is, as a specific example, a function that indicates a relation between the occurrence probability of an event and the smoothness, or a function that indicates a relation between a label corresponding to an event and the smoothness. When the smoothness decision function 19 is the function that indicates the relation between the occurrence probability of the event and the smoothness, the smoothness decision function 19 may be any function that increases monotonically.

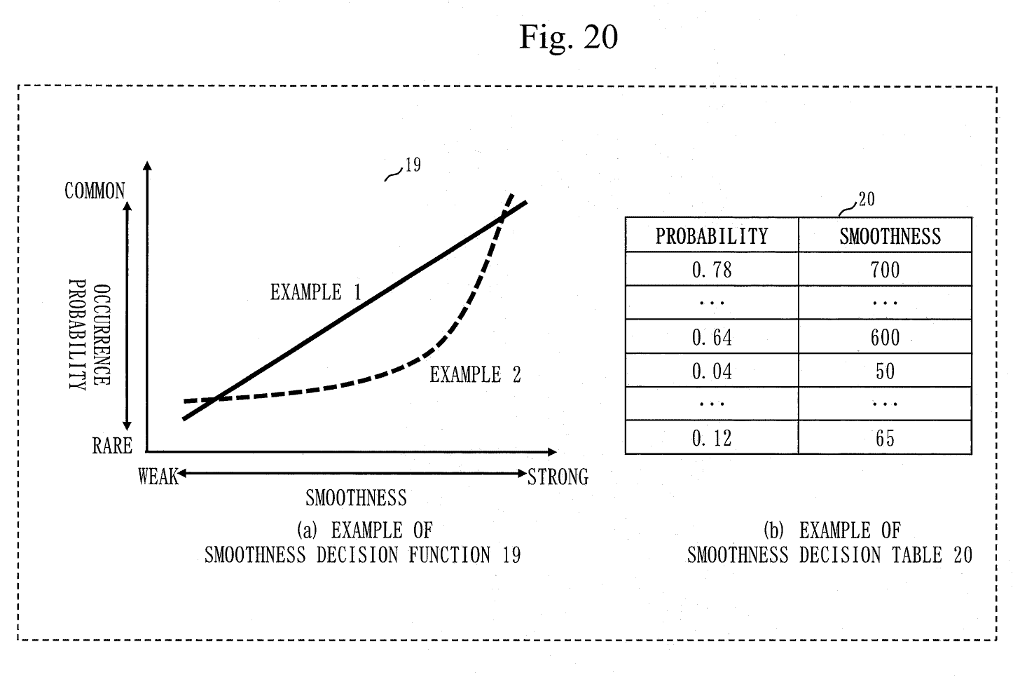

(a) of FIG. 20 illustrates two specific examples of the smoothness decision function 19. In the smoothness decision function 19, the lower the occurrence probability, the weaker the corresponding smoothness is, and the higher the occurrence probability, the stronger the corresponding smoothness is.

The smoothness decision table 20 is a table that illustrates a relation between the rarity of an event and the smoothness. The smoothness decision table 20 is, as a specific example, a table that indicates a relation between the occurrence probability of an event and the smoothness, or a table that illustrates a relation between a label corresponding to the event and the smoothness.

(b) of FIG. 20 illustrates a specific example of the smoothness decision table 20. The smoothness decision table 20 may also be a table that indicates a label instead of a probability.

### Description of Operation

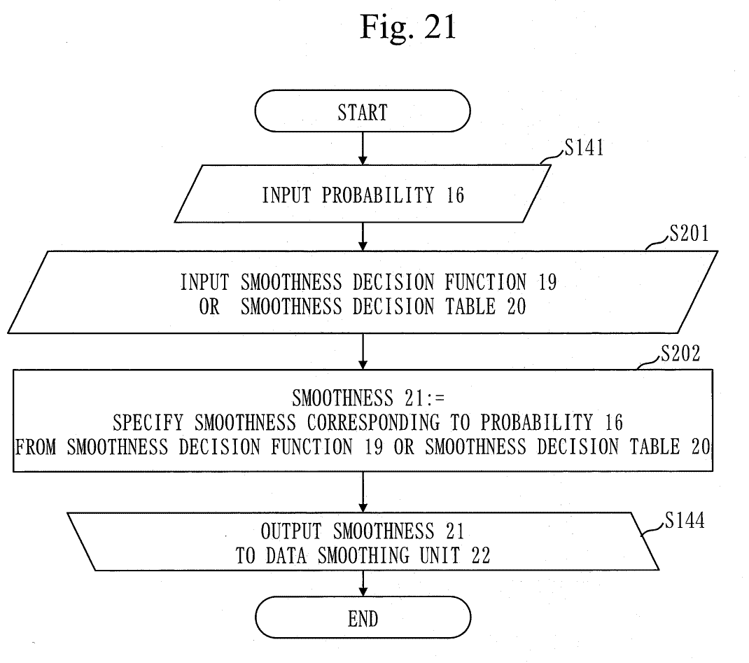

FIG. 21 is a flowchart illustrating an example of processing of the smoothness decision unit 18. The processing of the smoothness decision unit 18 will be described with reference to FIG. 21.

### (Step S201)

The smoothness decision unit 18 receives the smoothness decision function 19 or the smoothness decision table 20 from an external source.

### (Step S202)

The smoothness decision unit 18 specifies the smoothness 21 corresponding to the probability 16 based on the received smoothness decision function 19 or the smoothness decision table 20.

### Description of Effects of Embodiment 2

As described above, according to the present embodiment, by using the smoothness decision function 19 or the smoothness decision table 20 to specify the smoothness, it is not necessary to determine the smoothness from domain knowledge for each piece of time series data. It is also possible to seamlessly and automatically decide the smoothness according to the value of the data.

### Embodiment 3

In the following, the points that are different from the embodiments described above will be mainly described with reference to the drawings.

### Description of Configuration

An example of the configuration of the data storage system 90 according to the present embodiment is the same as the example of the configuration of the data storage system 90 according to the embodiments described above.

The data smoothing unit 22 according to the present embodiment smoothens the subject data using a weight that becomes larger as an event indicated by the subject data becomes rarer. Specifically, the data smoothing unit 22 uses a weighted moving average in smoothing. The weighted moving average is also known as a moving average that has multiplying factors. The weight is used to increase the value of a data point that has the low occurrence probability. The weight is, as a specific example, the reciprocal of the occurrence probability. [Formula 2] indicates a specific example of the weighted moving average. Here, PDF is the probability density function of the interpolated time series data 11, and xᵢ is a sample point (i=1, . . . , n) within Window in the moving average.

$$p = \frac{{\sum }_{i = 1}^{n} {w}_{i} {X}_{i}}{{\sum }_{i = 1}^{n} {w}_{i}} , {w}_{i} = \frac{1}{P D F ( {x}_{i} )} \qquad [ Formula 2 ]$$

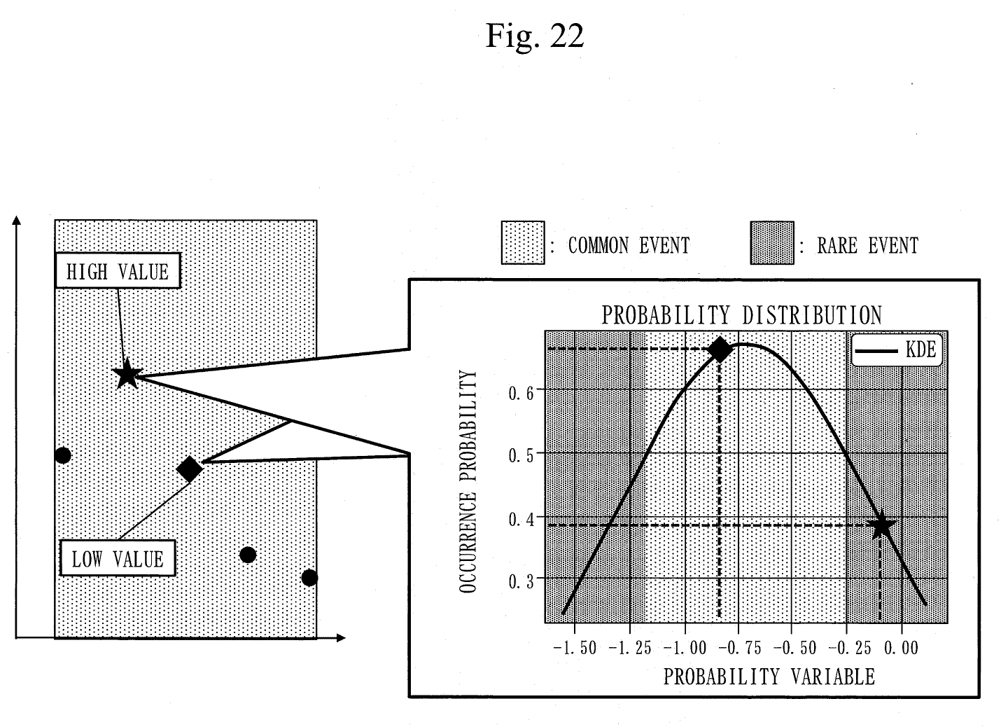

FIG. 22 illustrates how the weighting is applied by considering the values of the data points. The left side of FIG. 22 indicates Window used in the moving average, while the right side of FIG. 22 indicates the probability distribution that indicates the occurrence probability of each data point.

In the conventional moving average, as illustrated on the left side of FIG. 22, when the data with the high value and the data with the low value are mixed within Window, the value of the entire Window may be degraded. On the other hand, in the weighted moving average or the like, where the weights are the reciprocal of the occurrence probabilities, even when the data with the high value and the data with the low value are mixed within Window, the value of the entire Window is less likely to be degraded.

### Description of Operation

Differences between the operation of the data storage system 90 according to the present embodiment and the operation of the data storage system 90 according to the embodiments described above will be described.

In step S153, the data smoothing unit 22 uses the weighted moving average instead of a moving average or a spline smoothing function.

### Description of Effects of Embodiment 3

When a simple moving average is used in smoothing, the values of the sample points within Window are not sufficiently taken into account. On the other hand, according to the present embodiment, because the weighted moving average is used instead of the simple moving average, the values of the sample points within Window are taken into account. Therefore, according to the present embodiment, even if the smoothing is strengthened, the characteristics of the data are more likely to remain.

### Embodiment 4

In the following, the points that are different from the embodiments described above will be mainly described with reference to the drawings.

### Description of Configuration

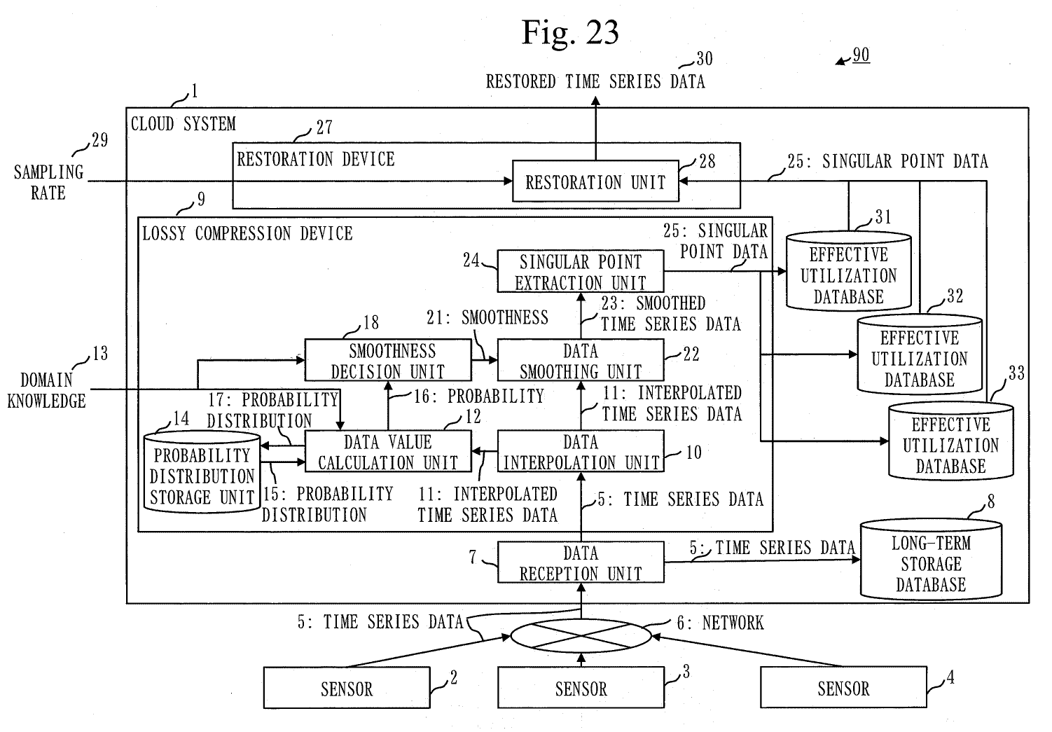

FIG. 23 illustrates an example of the configuration of the data storage system 90 according to the present embodiment.

The cloud system 1 according to the present embodiment includes an effective utilization database 31, an effective utilization database 32, and an effective utilization database 33.

The effective utilization database 31, the effective utilization database 32, and the effective utilization database 33 are equivalent to a plurality of effective utilization databases which are candidates for a storage location for the singular point data 25. A computational resource of each of the plurality of effective utilization databases may be different from each other. Each of the effective utilization database 31, the effective utilization database 32, and the effective utilization database 33 is the same as the effective utilization database 26.

The singular point extraction unit 24 according to the present embodiment selects an effective utilization database from the plurality of effective utilization databases, as the storage location for the singular point data 25. At this time, the singular point extraction unit 24 ensures that the singular point data 25 is stored in the effective utilization database with more computational resources as the utilization value of the singular point data 25 becomes higher.

As a specific example, the singular point extraction unit 24 distributes and outputs the singular point data 25 to the effective utilization database 31, the effective utilization database 32, and the effective utilization database 33. The number of databases that are output destinations of the singular point extraction unit 24 is not limited to three. At this time, as a specific example, the singular point extraction unit 24 distributes the singular point data 25 according to the usage frequency of the singular point data, the cumulative number of search hits of the singular point data, or the value of the time series data corresponding to the singular point data 25 (the probability 16). It is estimated that the higher the corresponding cumulative number of search hits, the higher the utilization value of the data.

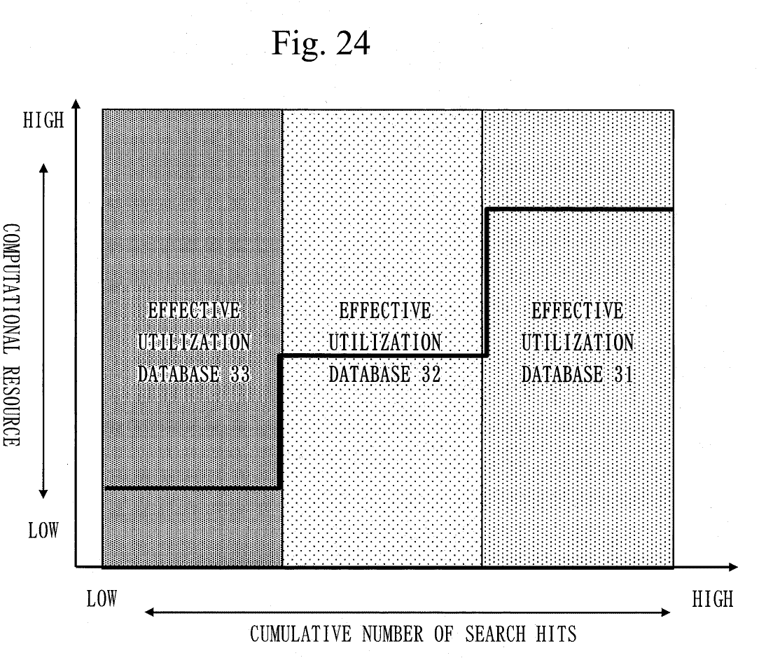

FIG. 24 is a diagram describing the process of distributing the singular point data 25 according to the cumulative number of search hits. As a specific example, the singular point extraction unit 24 distributes the singular point data 25, so that data with the cumulative number of search hits of 100 or more is stored in the effective utilization database 31, data with the cumulative number of search hits of 51 to 99 is stored in the effective utilization database 32, and data with the cumulative number of search hits of 50 or less is stored in the effective utilization database 33. In the present example, in order to increase the search speed, more computational resources such as CPU and memory resources are allocated to the effective utilization database 31. Similarly, the effective utilization database 32 is allocated fewer computational resources than the computational resources of the effective utilization database 31, and the effective utilization database 33 is allocated fewer computational resources than the computational resources of the effective utilization database 32. By allocating computational resources in such a way, it is possible to improve the response performance of searches on data that is used at a relatively high frequency, while reducing the operating cost of the database.

### Description of Operation

Differences between the operation of the data storage system 90 according to the present embodiment and the operation of the data storage system 90 according to the embodiments described above will be described.

In step S168, the singular point extraction unit 24 appropriately distributes the singular point data 25 to the effective utilization database 31, the effective utilization database 32, and the effective utilization database 33.

### Description of Effects of Embodiment 4

As described above, according to the present embodiment, by preparing a plurality of types of databases, and distributing the singular point data 25 to each database according to the value of the singular point data 25, it is possible to improve the response performance of searches on data that is used at a relatively high frequently, while reducing the operating cost of the database.

### Embodiment 5

In the following, the points that are different from the embodiments described above will be mainly described with reference to the drawings.

### Description of Configuration

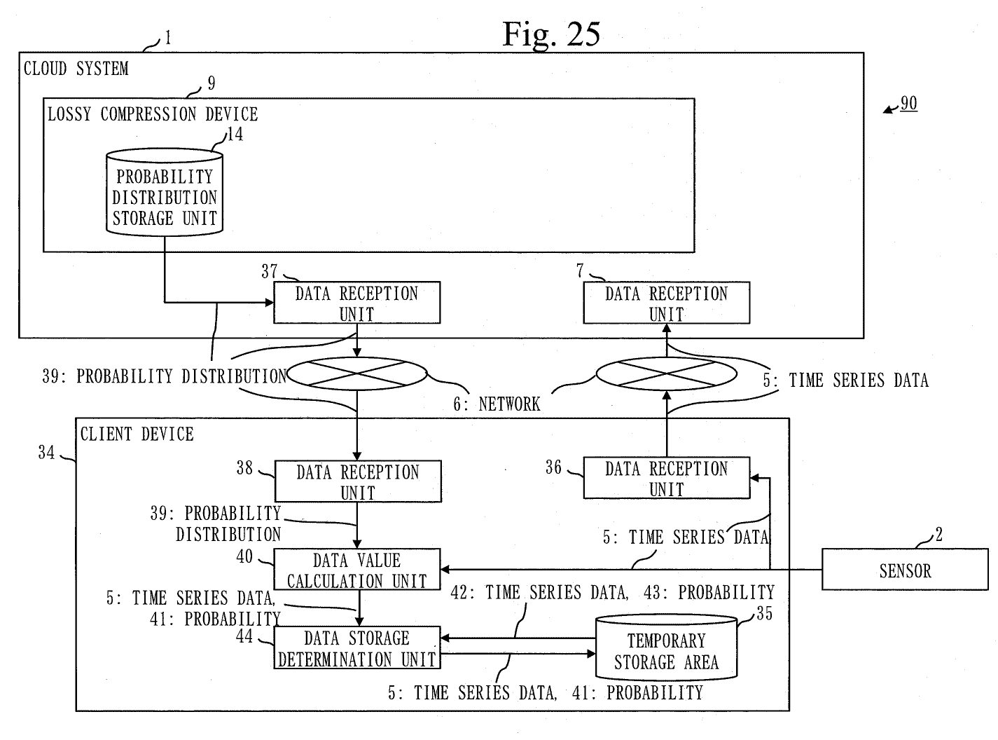

FIG. 25 illustrates an example of the configuration of the data storage system 90 according to the present embodiment. In FIG. 25, the distinctive configuration in the present embodiment is extracted. The configurations of the cloud system 1 and the like according to the present embodiment are basically as described above.

The data storage system 90 includes a client device 34. The client device 34 includes a temporary storage area 35, a data reception unit 36, a data reception unit 38, a data value calculation unit 40, and a data storage determination unit 44. The client device 34 is communicatively connected to the cloud system 1, and is communicatively connected to the lossy compression device 9 via a data reception unit 37.

The cloud system 1 according to the present embodiment includes the data reception unit 37.

Each of the data reception unit 36, the data reception unit 37, and the data reception unit 38 is the same as the data reception unit 7.

In the present embodiment, priority is given to time series data with a relatively high utilization value to be temporarily stored in the client device 34 for the purpose of backup or the like in case of a temporary network disconnection or the like. The client device 34 obtains in advance the utilization value (probability distribution or the like of data points) of the time series data calculated by the side of the cloud system 1, and determines whether the time series data 5 obtained at the time point of obtaining the time series data 5 is to be stored or not.

The client device 34 periodically transmits the time series data 5 measured by the sensor 2 to the cloud system 1 via the network 6. The number of sensors is not limited to one.

The temporary storage area 35 stores temporary storage data by associating it with the rarity of an event indicated by the temporary storage data. Specifically, the temporary storage area 35 stores the time series data 5 and the probability 41. The time series data 5 is equivalent to the temporary storage data.

The data value calculation unit 40 receives the time series data 5 from the sensor 2. Additionally, the data value calculation unit 40 receives from the probability distribution storage unit 14, the probability distribution 39 that represents the occurrence probability of each data point indicated by the time series data 5. Based on the received probability distribution 39, the data value calculation unit 40 specifies a probability corresponding to the data point with the lowest occurrence probability among the data points indicated by the time series data 5, and treats the specified probability as the probability 41. Subsequently, the data value calculation unit 40 outputs the time series data 5 and the probability 41 to the data storage determination unit 44.

The data storage determination unit 44 determines whether or not the subject data is temporarily stored in the temporary storage area 35 based on the result of comparing the rarity of the event indicated by the subject data and the rarity of the event indicated by the temporary storage data.

As a specific example, the data storage determination unit 44 receives the time series data 5 with the highest occurrence probability of corresponding representative point among the time series data 5 stored in the temporary storage area 35, as time series data 42. Also, the data storage determination unit 44 receives the probability 41 corresponding to the representative point of the time series data 42, as the probability 43. After that, when there is available space in the temporary storage area 35, the data storage determination unit 44 stores the time series data 5 and the probability 41 in the temporary storage area 35. When there is no available space in the temporary storage area 35, the data storage determination unit 44 compares the probability 41 with the probability 43. When the probability 41<the probability 43, the data storage determination unit 44 deletes the time series data 42 and the probability 43 from the temporary storage area 35 and stores the time series data 5 and the probability 41 in the temporary storage area 35. Further, when the probability 43≤the probability 41, the data storage determination unit 44 discards the time series data 5 and does not store the time series data 5 in the temporary storage area 35.

### Description of Operation

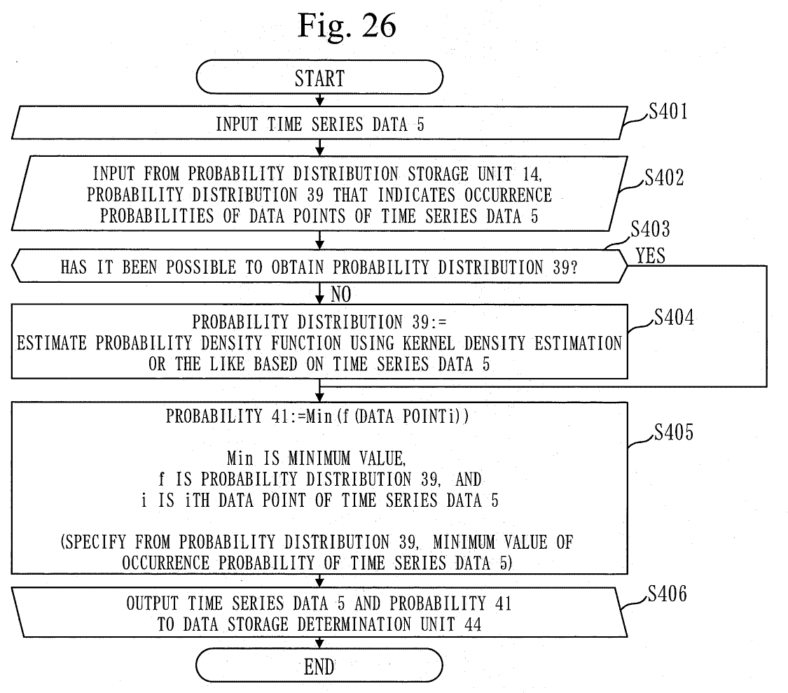

FIG. 26 is a flowchart illustrating an example of processing of the data value calculation unit 40. The processing of the data value calculation unit 40 will be described with reference to FIG. 26.

### (Step S401)

The data value calculation unit 40 receives the time series data 5 from the sensor 2.

### (Step S402)

The data value calculation unit 40 receives from the probability distribution storage unit 14, the probability distribution 39 that indicates the occurrence probability of each data point indicated by the time series data 5.

### (Step S403)

When the data value calculation unit 40 is able to obtain the probability distribution 39, the data value calculation unit 40 proceeds to step S405. Otherwise, the data value calculation unit 40 proceeds to step S404.

### (Step S404)

The data value calculation unit 40 estimates the probability density function using kernel density estimation or the like based on the received time series data 5, and treats the estimated probability density function as the probability distribution 39.

### (Step S405)

The data value calculation unit 40 specifies the minimum value of the occurrence probability of each data point indicated by the time series data 5 based on the probability distribution 39, as the probability 41.

### (Step S406)

The data value calculation unit 40 outputs each of the received time series data 5 and the specified probability 41 to the data storage determination unit 44.

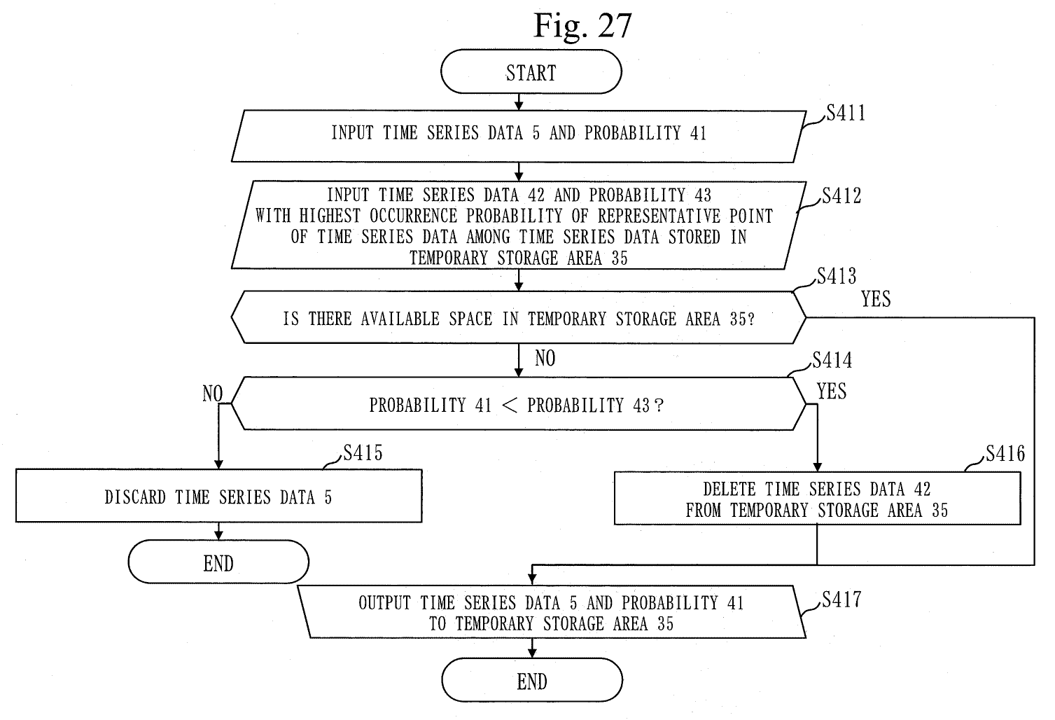

FIG. 27 is a flowchart illustrating an example of processing of the data storage

determination unit 44. The processing of the data storage determination unit 44 will be described with reference to FIG. 27.

### (Step S411)

The data storage determination unit 44 receives each of the time series data 5 and the probability 41 from the data value calculation unit 40.

### (Step S412)

The data storage determination unit 44 receives the time series data 5 with the highest occurrence probability of the corresponding representative point among the time series data 5 stored in the temporary storage area 35, as the time series data 42, and receives the probability 41 corresponding to the representative point of the time series data 42, as the probability 43.

### (Step S413)

When there is available space in the temporary storage area 35, the data storage determination unit 44 proceeds to step S417. Otherwise, the data storage determination unit 44 proceeds to step S414.

### (Step S414)

When the probability 41 <the probability 43, the data storage determination unit 44 proceeds to step S416. Otherwise, the data storage determination unit 44 proceeds to step S415.

### (Step S415)

The data storage determination unit 44 discards the received time series data 5.

### (Step S416)

The data storage determination unit 44 deletes the time series data 42 and the probability 43 from the temporary storage area 35.

### (Step S417)

The data storage determination unit 44 outputs the time series data 5 and the probability 41 to the temporary storage area 35.

### Description of Effects of Embodiment 5

As described above, according to the present embodiment, by prioritizing data with a relatively high utilization value to be stored in the client device 34, it is possible to increase the cost effectiveness of the device.

### Other Embodiments

Each of the above described embodiments can be freely combined, or any component of each of the embodiments can be modified. Alternatively, any component can be omitted in each of the embodiments.

Alternatively, the embodiments are not limited to those presented in Embodiments 1 to 5, and various modifications can be made as needed. The procedures described using the flowcharts or the like may be modified as appropriate.

### REFERENCE SIGNS LIST

1: cloud system; 2, 3, 4: sensor; 5: time series data; 6: network; 7: data reception unit; 8: long-term storage database; 9: lossy compression device; 10: data interpolation unit; 11: interpolated time series data; 12: data value calculation unit; 13: domain knowledge; 14: probability distribution storage unit; 15: probability distribution; 16: probability; 17: probability distribution; 18: smoothness decision unit; 19: smoothness decision function; 20: smoothness decision table; 21: smoothness; 22: data smoothing unit; 23: smoothed time series data; 24: singular point extraction unit; 25: singular point data; 26: effective utilization database; 27: restoration device; 28: restoration unit; 29: sampling rate; 30: restored time series data; 31, 32, 33: effective utilization database; 34: client device; 35: temporary storage area; 36, 37, 38: data reception unit; 39: probability distribution; 40: data value calculation unit; 41: probability; 42: time series data; 43: probability; 44: data storage determination unit; 51: processor; 52: memory; 53: auxiliary storage device; 54: input/output IF; 55: communication device; 58: processing circuit; 59: signal line; 90: data storage system.

1. A data storage system that stores data that is lossy compressed comprising
a lossy compression device that comprises processing circuitry:
to decide smoothness according to the rarity of an event indicated by subject data, as subject smoothness; and
to generate smoothed subject data by smoothing the subject data with the subject smoothness.

2. The data storage system according to claim 1, wherein
the processing circuitry calculates either an occurrence probability of a data point indicated by the subject data or an occurrence probability of a label assigned to the subject data, as the rarity of an event indicated by the subject data.

3. The data storage system according to claim 1, wherein
the processing circuitry decides the subject smoothness using data that indicates a relation between the rarity of an event indicated by the subject data and smoothness.

4. The data storage system according to claim 1, wherein
the processing circuitry smoothens the subject using a weight that becomes larger as an event indicated by the subject data becomes rarer.

5. The data storage system according to claim 1, wherein
the processing circuitry extracts a plurality of singular points from the smoothed subject data and generates singular point data that consists of the extracted plurality of singular points,
the data storage system further comprises a plurality of effective utilization databases which are candidates for a storage location for the singular point data,
a computational resource of each of the plurality of effective utilization databases is different from each other, and
the processing circuitry selects an effective utilization database from the plurality of effective utilization databases, as the storage location for the singular point data, and ensures that the singular point data is stored in the effective utilization database with more computational resources as the utilization value of the singular point data becomes higher.

6. The data storage system according to claim 1 further comprising
a client device that comprises
a temporary storage area that stores temporary storage data by associating it with the rarity of an event indicated by the temporary storage data, wherein
the processing circuitry determines whether or not to store the subject data in the temporary storage area based on a result of comparing the rarity of an event indicated by the subject data with the rarity of the event indicated by the temporary storage data, and
the lossy compression device is communicatively connected to the client device.

7. The data storage system according to claim 1 further comprising
a long-term storage database to store the subject data that is lossless compressed.

8. The data storage system according to claim 1, wherein
the subject data is time series data that indicates a measurement result of a sensor.

9. A data storage method to be executed in a data storage system that stores data that is lossy compressed comprising:
deciding smoothness according to the rarity of an event indicated by subject data, as subject smoothness; and
generating smoothed subject data by smoothing the subject data with the subject smoothness.

10. A non-transitory computer readable medium storing a data storage program for causing a lossy compression device which is a computer included in a data storage system that stores data that is lossy compressed to execute:
a smoothness decision process to decide smoothness according to the rarity of an event indicated by subject data, as subject smoothness; and
a data smoothing process to generate smoothed subject data by smoothing the subject data with the subject smoothness.
